(19) United States
(12) Patent Application Publication
(10) Pub. No.: US 2011/0012161 A1
(43) Pub. Date: Jan. 20, 2011

(54) MANUFACTURING METHODS AND INSTALLATION PROCEDURES WHICH CONFORMING TO THE INTERNATIONAL SAFETY CODES AND REGULATIONS FOR AC LED LAMP

(76) Inventor: Mien-Hsia HUNG, Chung-Ho City (TW)

Correspondence Address: Guice Patents PLLC, 12647 Galveston Court #302, Manassas, VA, 20112, US

(21) Appl. No.: 12/502,580

(22) Filed: Jul. 14, 2009

(51) Int. Cl. H01L 33/00; H01L 21/00

(52) U.S. Cl. 257/99; 438/26; 257/E33.059; 257/E21.052

(57) ABSTRACT

An alternating-current (AC) light-emitting diode (LED) lamp conforming to international safety regulations and a method for making the same are provided, wherein the core technique involves a circuit board made of a thermally conductive insulation material on which traces are provided, a chip is soldered, and an LED lighting unit is encapsulated. After the LED lighting unit is encapsulated on the circuit board, exposed and electrically conductive portions of the traces or solder points on the circuit board are encapsulated with a thermally resistant insulation material. Furthermore, a thermally conductive insulation plate is provided between the circuit board and a metal housing, and the circuit board is secured in position by fasteners made of an insulation material. Thus, electric shock is effectively prevented which may otherwise result from high-voltage current passing from electrically conductive ends of the circuit board to a heat dissipation mechanism (the metal housing).

### BACKGROUND OF THE INVENTION

1. Technical Field

The present invention relates to an alternating-current (AC) light-emitting diode (LED) lamp configured for effectively preventing electric shock and therefore conforming to international safety regulations, and a method for making the AC LED lamp, wherein the method and the AC LED lamp are characterized in that a circuit board is made of a thermally conductive insulation material and, after an LED lighting unit is encapsulated on the circuit board, exposed and electrically conductive portions of traces or solder points on the circuit board are encapsulated with a thermally resistant insulation material.

2. Description of Related Art

In a conventional LED lamp such as those shown in FIGS. 6, 10, and 12, an LED lighting unit 13 is directly encapsulated on a circuit board 5 made of a general resin or metal material. As would be understood by a person of ordinary skill in the art, a metallic or ceramic circuit board is obviously more effective than a resin circuit board in heat dissipation.

During the manufacturing process of the conventional LED lamp, the metallic or non-metallic circuit board 5, which is generally made of aluminum, copper, or ceramic, has its upper surface coated with an insulation layer, printed with traces, mounted with a chip by soldering, and then installed with the LED lighting unit 13 using an encapsulation technique. The resulting assembly is subsequently coupled, and hence makes close contact, with an electrically conductive, metallic heat dissipation mechanism 3, which is generally made of an aluminum or copper plate, such that heat generated by the LED lighting unit 13 is transferred rapidly through the thermally conductive, metallic or non-metallic circuit board 5 to the heat dissipation mechanism 3 and thereby dissipated.

As shown in FIGS. 6, 10, and 12, after the metallic or non-metallic circuit board 5 is installed in the LED lamp, metal traces 11 or solder points 14 on the metallic or non-metallic circuit board 5 are in close proximity to electrically conductive ends and electrically conductive end surfaces 51 of the metallic or non-metallic circuit board 5 and to the electrically conductive, metallic heat dissipation mechanism 3. Therefore, in case an abnormal condition such as short circuit or overloading occurs, electric current may pass from exposed and electrically conductive ends of the metallic or non-metallic circuit board 5 to the electrically conductive heat dissipation mechanism 3 due to an insufficient safety clearance therebetween. Since the aforesaid LED lamp is driven by a low-current, low-voltage direct-current (DC) power source, electric shock is unlikely to happen even if electric current passes on to the heat dissipation mechanism 3.

However, LED lamps driven directly by a high-voltage AC power source have been successfully developed in recent years. If an AC LED lamp is short-circuited or under abnormal load, electric current may pass from the high-voltage power source through a metallic or non-metallic circuit board or exposed and electrically conductive ends thereof to an electrically conductive heat dissipation mechanism and cause electric shock.

As safety regulations vary from country to country, the minimum required distance or spacing between the aforementioned high-voltage power driven metallic or non-metallic circuit board or electrically conductive ends thereof and any electrically conductive body varies. Taking UL1310, the US Standard for Class 2 Power Units, for example, it is stipulated that the spacing between two electrically conductive parts in high-voltage AC application shall be greater than 4.8 mm. Hence, the traditional LED lamps, whose metallic or non-metallic circuit board is bonded and fixed in position to a metal housing, apparently do not conform to such safety regulations.

### BRIEF SUMMARY OF THE INVENTION

In order to prevent electric shock which may otherwise result from the conventional LED lamps, this invention utilized manufacturing method and installation procedures which conform to the international safety regulations for making AC LED lamp. According to the present invention, a circuit board on which traces are provided, and to which a chip is soldered, and an LED lighting unit is encapsulated is made of a thermally conductive insulation material. In addition, after the LED lighting unit is encapsulated on the thermally conductive insulating circuit board, exposed and electrically conductive portions of the traces or solder points on the thermally conductive insulating circuit board are encapsulated with a thermally resistant insulation material so as to effectively prevent electric shock which may otherwise arise from electricity running from electrically conductive ends of the thermally conductive insulating circuit board to a heat dissipation mechanism.

The thermally conductive insulation material for making the circuit board mainly includes a thermally conductive but electrically non-conductive ceramic plate, among other thermally conductive insulation materials. The thermally resistant insulation material mainly includes various thermally resistant and electrically non-conductive resins, among other materials.

In addition, a thermally conductive insulation plate can be provided between the thermally conductive insulating circuit board and a metal housing, and fasteners for securing the circuit board in place are made of an insulation material so as to provide enhanced protection against electric shock.

### BRIEF DESCRIPTION OF THE SEVERAL VIEWS OF THE DRAWINGS

The invention as well as a preferred mode of use, further objectives, and advantages thereof will be best understood by referring to the following detailed description of illustrative embodiments in conjunction with the accompanying drawings, wherein:

FIG. 1 is a perspective view of a circuit board of an LED lamp according to the present invention, wherein the circuit board is made of a thermally conductive insulation material;

FIG. 2 is a perspective view of the circuit board shown in FIG. 1, after traces are provided on, and a chip is soldered to, the circuit board;

FIG. 3 is a perspective view of the circuit board shown in FIG. 2, after an LED lighting unit is encapsulated on the circuit board;

FIG. 4 is a perspective view of the circuit board shown in FIG. 3, after encapsulation is completed;

FIG. 5 is a sectional view of the completely assembled safety circuit board shown in FIG. 4, when installed in an LED lamp according to the present invention;

FIG. 6 is a sectional view of a conventional LED lamp and a circuit board installed therein;

FIG. 7 is a perspective view of another embodiment of the circuit board according to the present invention;

FIG. 8 is a perspective view of the circuit board shown in FIG. 7, after the circuit board is provided with traces, mounted with a chip by soldering, installed with an LED lighting unit by an encapsulation technique, and finished with encapsulation;

FIG. 9 is a perspective view of an LED lamp to which the circuit board according to the present invention is applied;

FIG. 10 is a perspective view of yet another conventional LED lamp and a circuit board installed therein;

FIG. 11 is a perspective view of another LED lamp to which the circuit board according to the present invention is applied; and

FIG. 12 is a perspective view of still another conventional LED lamp and circuit boards installed therein.

### DETAILED DESCRIPTION OF THE INVENTION

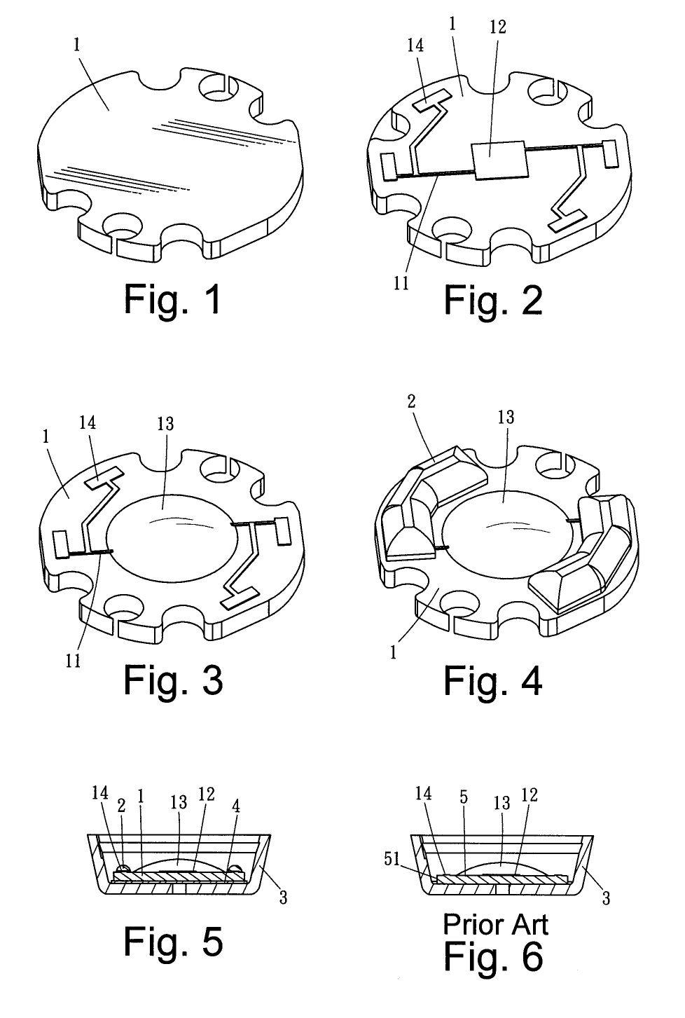

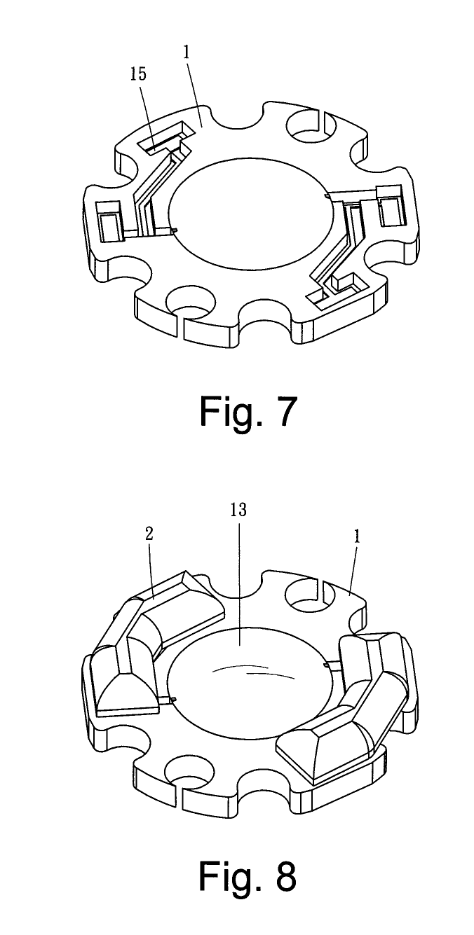

This invention utilized manufacturing method and installation procedures which conform to the international safety regulations for making AC LED lamp. Referring to FIG. 1, a thermally conductive insulating circuit board 1 made of a thermally conductive insulation material is provided for use in an LED lamp. Referring to FIG. 2 and FIG. 3, the thermally conductive insulating circuit board 1 is printed or otherwise provided with traces 11, mounted with a chip 12 by soldering, and installed with an LED lighting unit 13 using an encapsulation technique. Referring to FIG. 4 and FIG. 5, after the encapsulation of the LED lighting unit 13, exposed and electrically conductive portions of the traces 11 or solder points 14 on the thermally conductive insulating circuit board 1 are encapsulated with a thermally resistant insulation material 2 for insulation. Referring to FIG. 7 and FIG. 8, in order to increase the distance between the traces 11, which are made of metal, or the solder points 14 on the thermally conductive insulating circuit board 1 and an electrically conductive, metallic heat dissipation mechanism 3 or any other electrically conductive body, the thermally conductive insulating circuit board 1 is formed with a groove 15 corresponding in position to the metal traces 11 or the solder points 14 such that the traces 11 are printed or otherwise provided in the groove 15, the chip 12 is soldered to the groove 15, and the LED lighting unit 13 is encapsulated at a location corresponding to the groove 15, before the exposed and electrically conductive portions of the traces 11 or the solder points 14 are encapsulated with the thermally resistant insulation material 2 for insulation. Thus, the distance between the metal traces 11 or the solder points 14 on the thermally conductive insulating circuit board 1 and the electrically conductive, metallic heat dissipation mechanism 3 or any other electrically conductive body is increased to provide better protection against electric shock.

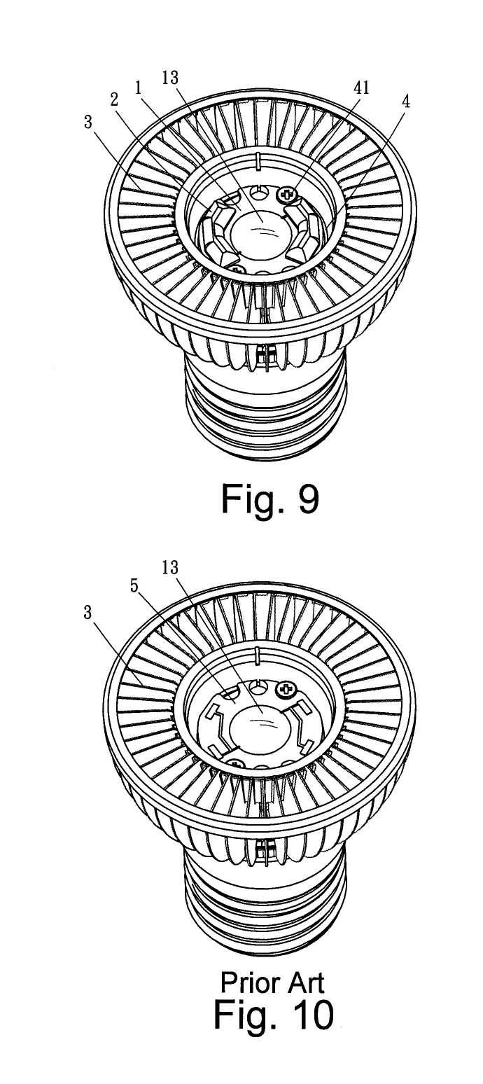

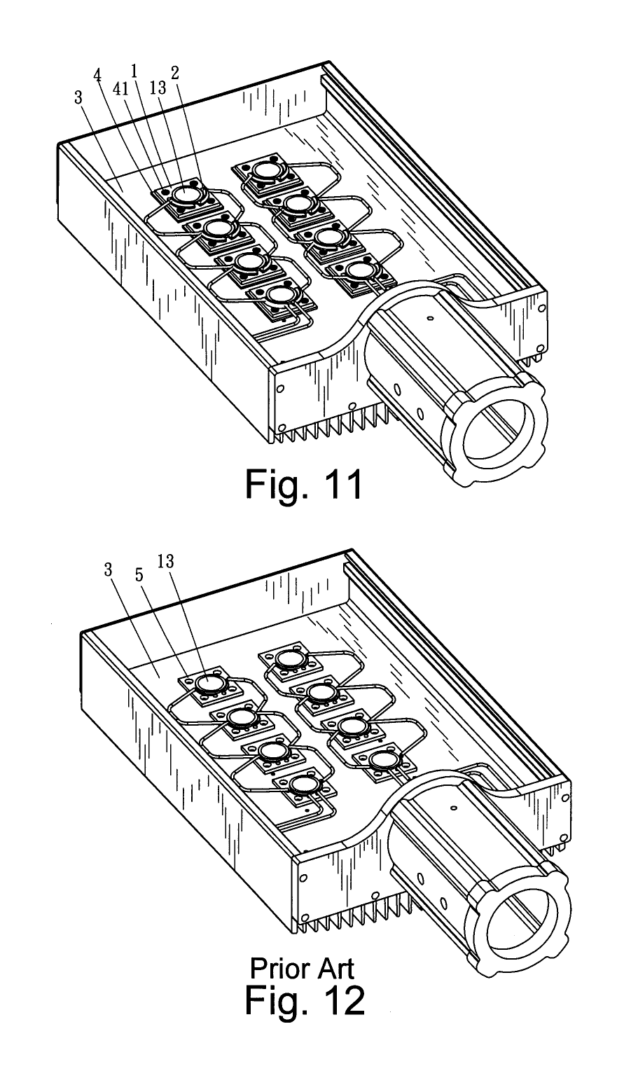

As shown in FIG. 9 and FIG. 11, the thermally conductive insulating circuit board 1 made according to the present invention is coupled with electrically conductive, metallic heat dissipation mechanisms 3 of different configurations and used in an LED lamp and a street lamp, respectively. With the aforementioned structure, the LED lamp and street lamp made according to the present invention are obviously highly capable of preventing current leakage or electric shock.

In addition, a thermally conductive insulation plate 4 may also be provided between the thermally conductive insulating circuit board 1 and the electrically conductive, metallic heat dissipation mechanism 3. Furthermore, fasteners 41 for securing the thermally conductive insulating circuit board 1 in position, such as screws, rivets, and retainers, are made of an insulation material so as to provide enhanced protection against electric shock.

The thermally conductive insulating circuit board 1 and the thermally conductive insulation plate 4 are made of a thermally conductive insulation material such as a ceramic plate, an aluminum substrate or copper substrate peripherally plated with an insulation material, a carbon fiber substrate, a mica plate, a quartz plate, and a glass fiber plate.

The thermally resistant insulation material 2 for encapsulation can be selected from various thermally resistant and electrically non-conductive resins, among other thermally resistant and electrically non-conductive materials.

Hence, the method and the AC LED lamp according to the present invention effectively prevent electric shock which may otherwise result accidentally by electric current running from electrically conductive ends of the thermally conductive insulating circuit board 1 to the heat dissipation mechanism 3.

What is claimed is:

1. A method for making an alternating-current (AC) light-emitting diode (LED) lamp conforming to international safety regulations, the method comprising steps of:
providing a thermally conductive insulating circuit board to be coupled fixedly with an electrically conductive, metallic heat dissipation mechanism;
printing or otherwise providing traces on the thermally conductive insulating circuit board;
soldering a chip to the thermally conductive insulating circuit board;
encapsulating an LED lighting unit on the thermally conductive insulating circuit board; and
encapsulating exposed and electrically conductive portions of the traces or solder points on the thermally conductive insulating circuit board with a thermally resistant insulation material for insulation.

2. The method of claim 1, further comprising forming a groove on the thermally conductive insulating circuit board, wherein the groove corresponds in position to the traces, which are made of metal, or to the solder points such that the traces are printed or otherwise provided in the groove, the chip is soldered to the groove, and the LED lighting unit is encapsulated at a position corresponding to the groove before the exposed and electrically conductive portions of the metal traces or the solder points on the thermally conductive insulating circuit board are encapsulated with the thermally resistant insulation material for insulation, so as to increase a distance from the metal traces or the solder points on the thermally conductive insulating circuit board to the electrically conductive, metallic heat dissipation mechanism or any other electrically conductive body, thereby enhancing safety of the AC LED lamp.

3. The method of claim 1, wherein the thermally conductive insulating circuit board is made of a thermally conductive insulation material selected from the group consisting of ceramic, an aluminum substrate or copper substrate peripherally plated with an insulation material, a carbon fiber substrate, a mica substrate, a quartz substrate, and a glass fiber substrate.

4. The method of claim 1, wherein the thermally resistant insulation material used for the encapsulating is selected from the group consisting of various thermally resistant and electrically non-conductive resins.

5. An alternating-current (AC) light-emitting diode (LED) lamp conforming to international safety regulations, the AC LED lamp comprising an electrically conductive, metallic heat dissipation mechanism and a thermally conductive insulating circuit board in contact with the electrically conductive, metallic heat dissipation mechanism, wherein in a region of the thermally conductive insulating circuit board other than where an LED lighting unit is encapsulated, exposed and electrically conductive portions of traces or solder points on the thermally conductive insulating circuit board are encapsulated with a thermally resistant insulation material.

6. The AC LED lamp of claim 5, wherein the thermally conductive insulating circuit board is formed with a groove corresponding in position to the traces, which are made of metal, or to the solder points such that the traces are printed or otherwise provided in the groove, a chip is soldered to the groove, and the LED lighting unit is encapsulated at a position corresponding to the groove before the exposed and electrically conductive portions of the metal traces or the solder points on the thermally conductive insulating circuit board are encapsulated with the thermally resistant insulation material for insulation, so as to increase a distance from the metal traces or the solder points on the thermally conductive insulating circuit board to the electrically conductive, metallic heat dissipation mechanism or any other electrically conductive body, thereby enhancing safety of the AC LED lamp.

7. The AC LED lamp of claim 5, wherein the thermally conductive insulating circuit board is made of a thermally conductive insulation material selected from the group consisting of ceramic, an aluminum substrate or copper substrate peripherally plated with an insulation material, a carbon fiber substrate, a mica substrate, a quartz substrate, and a glass fiber substrate.

8. The AC LED lamp of claim 5, wherein the thermally resistant insulation material used for the encapsulating is selected from the group consisting of various thermally resistant and electrically non-conductive resins.

9. The AC LED lamp of claim 5, further comprising a thermally conductive insulation plate disposed between the thermally conductive insulating circuit board and the electrically conductive, metallic heat dissipation mechanism, wherein the thermally conductive insulating circuit board is secured in position by fasteners made of an insulation material.

10. The AC LED lamp of claim 9, wherein the thermally conductive insulation plate is selected from the group consisting of a ceramic plate, an aluminum substrate or copper substrate peripherally plated with an insulation material, a carbon fiber substrate, a mica substrate, a quartz substrate, and a glass fiber substrate.
